(19) United States
(12) Patent Application Publication
(10) Pub. No.: US 2008/0054450 A1
(43) Pub. Date: Mar. 6, 2008

(54) CHIP PACKAGE STRUCTURE AND HEAT SINK FOR CHIP PACKAGE

(75) Inventors: Chi-Tsung Chiu, Kaohsiung (TW); Chih-Pin Hung, Kaohsiung (TW); Ying-Te Ou, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/831,412

(22) Filed: Jul. 31, 2007

(30) Foreign Application Priority Data
Sep. 6, 2006 (TW) 95132839

(51) Int. Cl. H01L 23/34; H05K 7/20

(52) U.S. Cl. 257/717; 361/710; 257/E23.08

(57) ABSTRACT

A chip package structure including a circuit substrate, a chip, a heat sink, and at least one electrical connector is provided. The circuit substrate has a carrying surface and at least one contact disposed on the carrying surface. The chip is disposed on the carrying surface and electrically connected to the circuit substrate. The heat sink is disposed on the carrying surface and includes a thermal conductive body, at least one passive device, and at least one electrical conductive terminal. The thermal conductive body has a bonding surface and the passive device is embedded in the thermal conductive body. The electrical conductive terminal is connected to the passive device. The electrical connector is disposed between the electrical conductive terminal and the corresponding contact, such that the circuit substrate is electrically connected to the passive device. Since the passive device is disposed in the heat sink, the layout space is increased.

### CROSS-REFERENCE TO RELATED APPLICATION

This application claims the priority benefit of Taiwan application serial no. 95132839, filed on Sep. 6, 2006. All disclosure of the Taiwan application is incorporated herein by reference.

### BACKGROUND OF THE INVENTION

1. Field of the Invention

The present invention relates to a chip package structure, and more particularly, to a chip package structure having a heat sink.

2. Description of Related Art

A flip chip package technology mainly includes disposing a plurality of bonding pads on an active surface of a chip, and forming bumps on the bonding pads respectively, such that the chip is capable of being electrically connected to the circuit substrate through the bumps on the bonding pads. It should be noted that as the flip chip bonding technology can be applied to a chip package structure of high pin count, and has advantages of reduced package area and shortened signal transmission path, the flip chip package technology has been widely applied in the chip package field.

However, along with the requirements of higher performance and integration, a circuit density of the flip chip package becomes higher and higher. Besides, as the number of the passive devices carried on the chip becomes more, and further the requirements of heat dissipation of the chip and supporting an integrated circuit (IC) board, the probability of designing a chip carrying a heat sink is gradually paid more attention.

In a conventional flip chip package structure, passive devices are usually disposed in the periphery of the chip. As the circuit density of the flip chip package becomes higher, the circuit layout space of a circuit layer at the top layer of the circuit substrate is further limited. However, along with the improvement of the performance of the chip, the circuits at the top layer of the circuit substrate must be added. Thus, the space of attaching the heat sink on the circuit substrate or the space of disposing the passive devices on the circuit substrate is limited, such that the heat sink or more passive devices cannot be disposed on the circuit substrate.

### SUMMARY OF THE INVENTION

The present invention is directed to a chip package structure, so as to increase the layout space of the circuit substrate.

The present invention is also directed to a heat sink for a chip package, so as to increase the layout space of the circuit substrate.

As embodied and broadly described herein, a heat sink for a chip package is provided. The heat sink mainly includes a thermal conductive body, at least one passive device, and at least one electrical conductive terminal. The thermal conductive body has a bonding surface, and the passive device is embedded in the thermal conductive body and is connected to the electrical conductive terminal.

A chip package structure including a circuit substrate, a chip, the above-mentioned heat sink, and at least one electrical connector is provided. The circuit substrate has a carrying surface and at least one contact disposed on the carrying surface. The chip is disposed on the carrying surface and electrically connected to the circuit substrate. The heat sink is disposed on the carrying surface. The electrical connector is disposed between the electrical conductive terminal and the corresponding contact, such that the circuit substrate is electrically connected to the passive device.

According to an embodiment of the present invention, a material of the thermal conductive body includes ceramic material.

According to an embodiment of the present invention, the heat sink further includes at least one first bonding pad disposed on the bonding surface. At least one second bonding pad corresponding to the first bonding pad is disposed on the carrying surface of the circuit substrate. The chip package structure further includes a bonding material disposed between the first bonding pad and the corresponding second bonding pad.

According to an embodiment of the present invention, the first bonding pad and the second bonding pad are correspondingly disposed in a corner of the thermal conductive body.

According to an embodiment of the present invention, the at least one passive device is disposed in an array in the thermal conductive body.

According to an embodiment of the present invention, the shape of the thermal conductive body is rectangular, and the at least one electrical conductive terminal is distributed along diagonal lines of the thermal conductive body.

According to an embodiment of the present invention, the at least one electrical conductive terminal is disposed in an array on the bonding surface.

According to an embodiment of the present invention, a chip exposure opening is formed in the thermal conductive body for exposing a top surface of the chip.

According to an embodiment of the present invention, a chip accommodating cavity is formed on the bonding surface for accommodating the chip.

According to an embodiment of the present invention, the chip package structure further includes a thermal interface material (TIM) disposed between the chip and the heat sink.

According to an embodiment of the present invention, the chip is bonded to the circuit substrate by means of flip chip.

In the present invention, the passive device is integrated into the heat sink, so the layout space of the circuit substrate is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a bottom view of a heat sink according to an embodiment of the present invention.

FIG. 1B is a top view of FIG. 1A.

FIG. 1C is a schematic side view of FIG. 1A.

FIG. 2A is a bottom view of a heat sink according to another embodiment of the present invention.

FIG. 2B is a top view of FIG. 2A.

FIG. 2C is a schematic side view of FIG. 2A.

FIG. 3A is a bottom view of a heat sink according to still another embodiment of the present invention.

FIG. 3B is a top view of FIG. 3A.

FIG. 3C is a schematic side view of FIG. 3A.

### DESCRIPTION OF EMBODIMENTS

The present invention mainly relates to positions of the passive devices, and the design of integrating the passive devices in a heat sink. Those in the art should understand the package processes and structures of the chip and the circuit substrate, and the materials of all components, and the details will not be described herein again in the following embodiments.

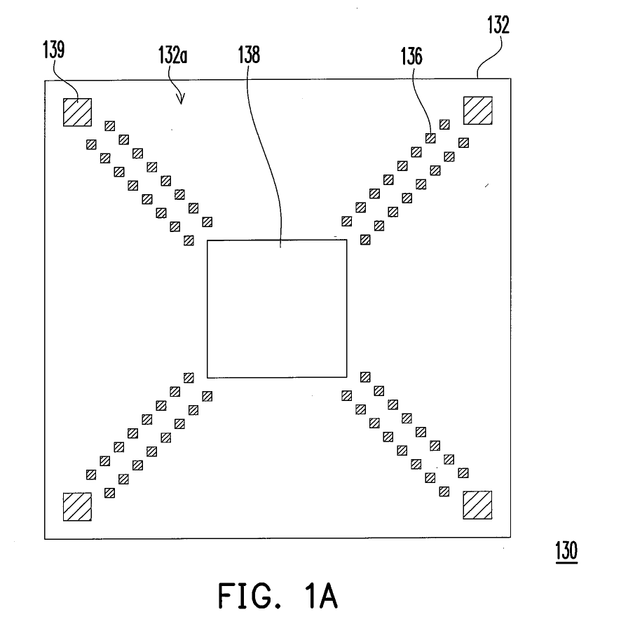

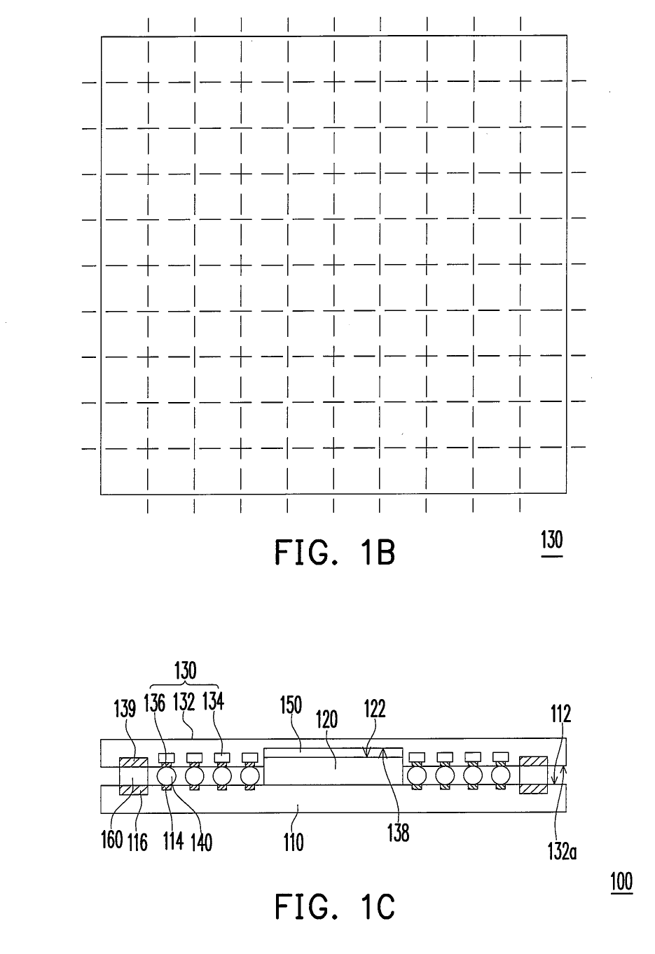

FIG. 1A is a bottom view of a heat sink according to an embodiment of the present invention, FIG. 1B is a top view of FIG. 1A, and FIG. 1C is a schematic side view of FIG. 1A. First, referring to FIGS. 1A and 1C, the chip package structure 100 of the present invention includes a circuit substrate 110, a chip 120, a heat sink 130, and a plurality of electrical connectors 140. The circuit substrate 110 has a carrying surface 112 and a plurality of contacts 114 disposed on the carrying surface 112. The chip 120 is disposed on the carrying surface 112, and electrically connected to the circuit substrate 110. The heat sink 130 is disposed on the carrying surface 112, and includes a thermal conductive body 132, a plurality of passive devices 134, and a plurality of electrical conductive terminals 136. Further, the thermal conductive body 132 has a bonding surface 132a. The passive devices 134 are embedded in the thermal conductive body 132, and the electrical conductive terminals 136 are connected to the passive devices 134 respectively. In addition, each electrical connector 140 is disposed between the corresponding electrical conductive terminal 136 and the corresponding contact 114, such that the circuit substrate 110 is electrically connected to the passive devices 134.

In the present invention, the chip 120 is bonded to the circuit substrate 110 by means of flip chip or in other manners. Besides, the chip package structure 100 further includes a TIM 150 disposed between the chip 120 and the heat sink 130, so as to enhance a thermal conductivity between the chip 120 and the heat sink 130. The thermal conductive body 132 is, for example, formed by a ceramic material or other materials of good thermal conductivity. Further, the electrical connectors 140 are formed by solder balls or other connection materials. In addition, the passive devices 134 are, for example, composed of at least one of the resistors, inductors, or capacitors. For example, all the passive devices 134 can be capacitors, and the passive devices 134 can also be constituted by a part of capacitors and a part of inductors.

Next, referring to FIG. 1B, in the heat sink 130, each block partitioned by the dashed line can be regarded as having a passive device 134 embedded therein. In other words, the passive devices 134 are, for example, disposed in an array in the thermal conductive body 132, as shown in FIG. 1B. Afterwards, referring to FIG. 1A, the electrical conductive terminals 136 are, for example, distributed on the bonding surface 132a of the thermal conductive body 132 along the diagonal lines of the thermal conductive body 132, as shown in FIG. 1A.

Further, referring to FIG. 1C, in order to reduce the overall height of the chip package structure 100, the present invention can selectively form a chip accommodating cavity 138 on the bonding surface 132a of the thermal conductive body 132, for accommodating the chip 120. Moreover, before the heat sink 130 is bonded, the TIM 150 can be disposed in the chip accommodating cavity 138, and the bonding surface 132a of the thermal conductive body 132 is bonded to the top surface 122 of the chip 120 through the TIM 150. Furthermore, as the top surface of the heat sink 130 is a plane, a heat sink fin or a fan can be further disposed on the top surface of the heat sink 130, so as to enhance the overall heat dissipation efficiency of the chip package structure 100.

Besides, in the present invention, in order to reinforce the bonding strength between the heat sink 130 and the circuit substrate 110, a connector having structure bonding effect purely is disposed between the bonding surface 132a of the thermal conductive body 132 and the carrying surface 112 of the circuit substrate 110. In particular, as shown in FIGS. 1A and 1B, a plurality of first bonding pads 139 is disposed on the bonding surface 132a of the thermal conductive body 132, and a plurality of second bonding pads 116 is disposed on the carrying surface 112 of the circuit substrate 110. A bonding material 160, for example, a solder or other materials of good bonding effect, is disposed between the corresponding first bonding pad 139 and the corresponding second bonding pad 116. In this embodiment, the first bonding pads 139 and the second bonding pads 116 are, for example, correspondingly disposed in corners of the thermal conductive body 132. However, the position and number of the first bonding pads 139 and the second bonding pads 116 are not limited in the present invention.

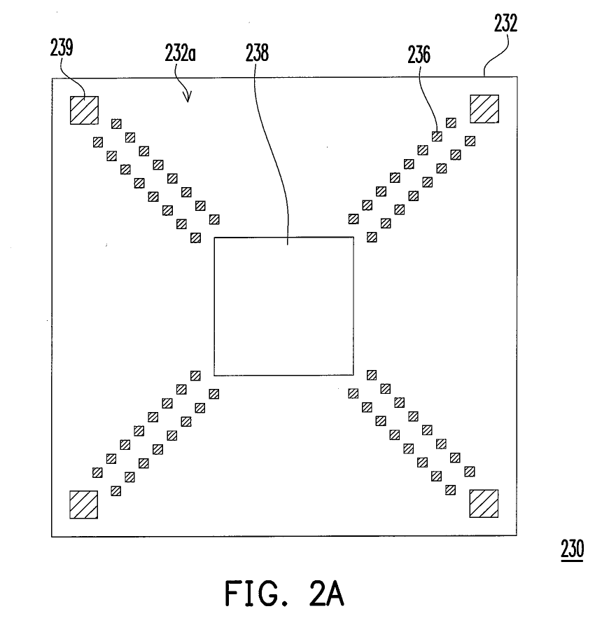

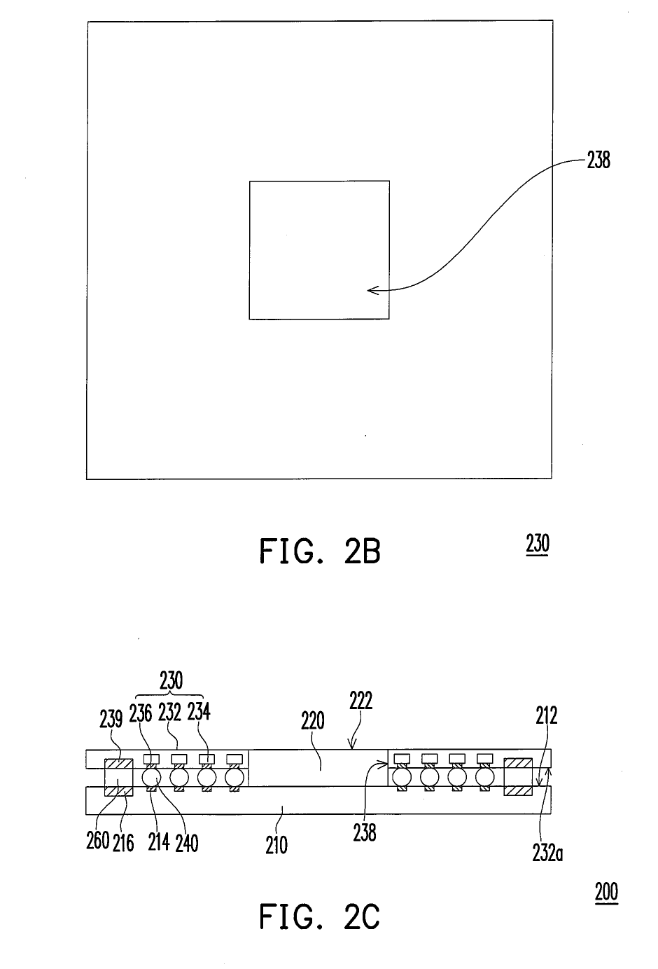

FIG. 2A is a bottom view of a heat sink according to another embodiment of the present invention, FIG. 2B is a top view of FIG. 2A, and FIG. 2C is a schematic side view of FIG. 2A. Referring to FIGS. 2A, 2B, and 2C together, the chip package structure 200 is substantially identical to the chip package structure 100 as shown in FIGS. 1A and 1B. The difference between the above two structures lies in that the thermal conductive body 232 has a chip exposure opening 238 for exposing the top surface 222 of the chip 220, instead of the chip accommodating cavity 138 for accommodating the chip 120. Therefore, in the chip package structure 200, when a heat sink fin or a fan is disposed on the top surface of the heat sink 230, the heat sink fin or the fan can be directly in contact with the top surface 222 of the chip 220, thus further enhancing the heat dissipation efficiency of the chip 222.

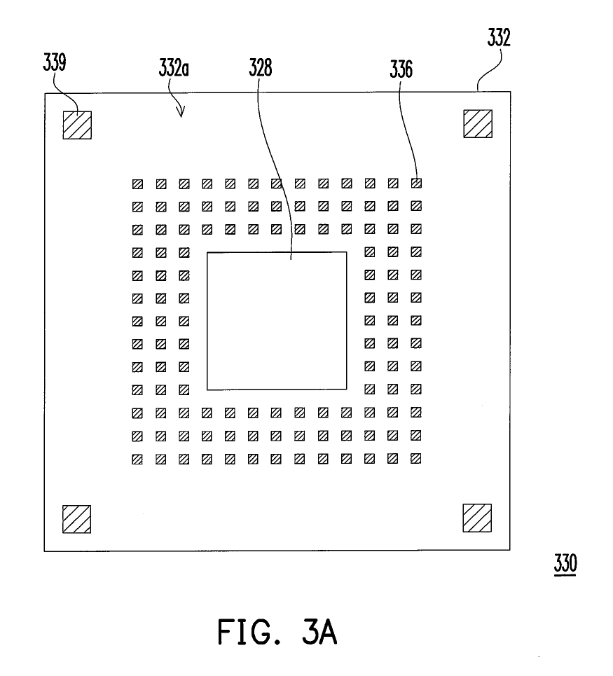

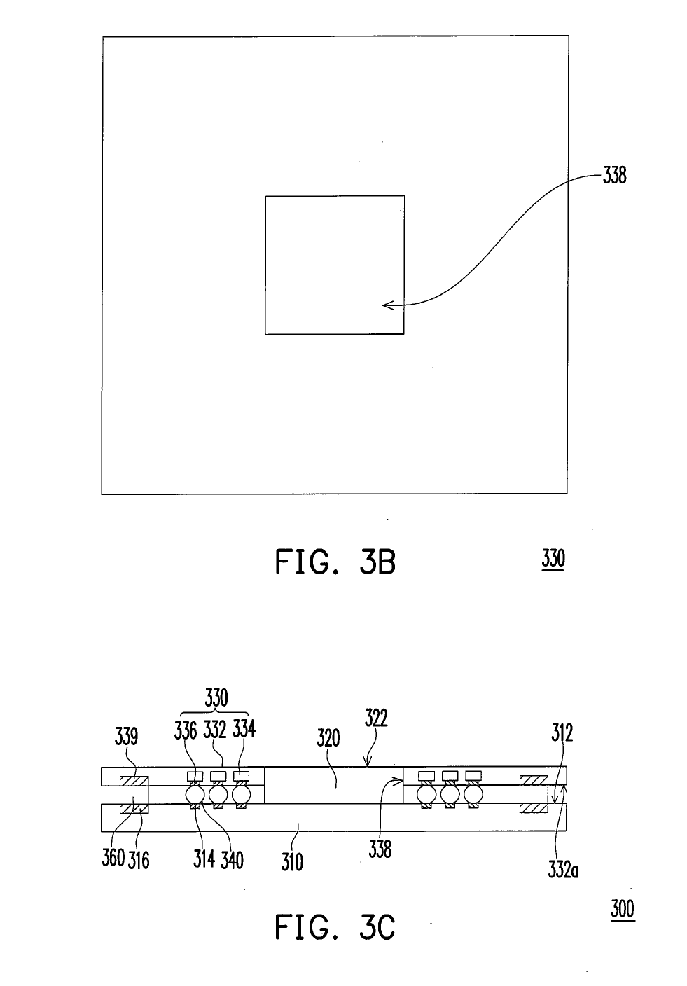

FIG. 3A is a bottom view of a heat sink according to still another embodiment of the present invention, FIG. 3B is a top view of FIG. 3A, and FIG. 3C is a schematic side view of FIG. 3A. Referring to FIGS. 3A, 3B, and 3C together, the chip package structure 300 is substantially identical to the chip package structure 200 as shown in FIGS. 2A, 2B, and 2C. The difference between the above two structures lies in that the electrical conductive terminals 336 are distributed in an array on the bonding surface 332a of the thermal conductive body 332, instead of being distributed on the bonding surface 232a of the thermal conductive body 232 along the diagonal lines of the thermal conductive body 232 as shown in FIG. 2A. Definitely, the relative positions of the passive devices 334 and the electrical conductive terminals 336 are not absolutely related. Moreover, the positions and arrangements of the passive devices 334 and the electrical conductive terminals 336 are not limited by the present invention, and persons in the art can obtain an optimal design as required, for example, according to the layout of the contacts 314 and the circuits on the circuit substrate 310.

Besides, it should be noted that the present invention can adjust the number of the passive devices to be connected, i.e., only some of the electrical conductive terminals are electrically connected to the corresponding contacts. In particular, the electrical connectors can be selectively disposed between some of the electrical conductive terminals of the heat sink and some of the corresponding contacts of the circuit substrate, so as to active some of the corresponding passive devices to adjust the resistance, inductance, or capacitance value required by the chip in operation.

Further, in the above embodiments, the number of the electrical connectors, contacts, passive devices, and electrical conductive terminals are more than one, so as to clearly illustrate the arrangement and the relation of the devices. However, the present invention is not limited to the above embodiments. In other words, the number of the electrical connectors, contacts, passive devices, and electrical conductive terminals is at least one.

In view of the above, according to the present invention, the passive devices are integrated in the heat sink to replace the conventional design of disposing the passive devices on the circuit substrate in the periphery of the chip. As such, the passive devices do not occupy the layout space, thus preserving the layout space required for enhancing the chip performance, and reducing the overall height of the chip package structure. Moreover, the present invention can adjust the number of the passive devices to be connected as required, such that in the chip package structure, the resistance, inductance, or capacitance value required by the chip in operation can be adjusted. Besides, the design of a chip accommodating cavity or a chip exposure opening can further reduce the overall height of the chip package structure. In addition, according to the design that some of the electrical conductive terminals are not electrically connected to the corresponding contacts, a proper number of passive devices can be connected according to user's requirements, such that the present invention is applicable to diversified chip designs.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A chip package structure, comprising:
a circuit substrate, having a carrying surface and at least one contact disposed on the carrying surface;
a chip, disposed on the carrying surface, and electrically connected to the circuit substrate;
a heat sink, disposed on the carrying surface, the heat sink comprising:
a thermal conductive body, having a bonding surface;
at least one passive device, embedded in the thermal conductive body;
at least one electrical conductive terminal, connected to the passive device; and
at least one electrical connector, disposed between the electrical conductive terminal and the corresponding contact, such that the circuit substrate is electrically connected to the passive device.

2. The chip package structure as claimed in claim 1, wherein a material of the thermal conductive body comprises ceramic material.

3. The chip package structure as claimed in claim 1, wherein the heat sink further comprises at least one first bonding pad disposed on the bonding surface, and at least one second bonding pad corresponding to the first bonding pad is disposed on the carrying surface of the circuit substrate; the chip package structure further comprises a bonding material disposed between the first bonding pad and the corresponding second bonding pad.

4. The chip package structure as claimed in claim 3, wherein the first bonding pad and the second bonding pad are correspondingly disposed in a corner of the thermal conductive body.

5. The chip package structure as claimed in claim 1, wherein the at least one passive device is disposed in an array in the thermal conductive body.

6. The chip package structure as claimed in claim 1, wherein the shape of the thermal conductive body is rectangular, and the at least one electrical conductive terminal is distributed along diagonal lines of the thermal conductive body.

7. The chip package structure as claimed in claim 1, wherein the at least one electrical conductive terminal is disposed in an array on the bonding surface.

8. The chip package structure as claimed in claim 1, wherein a chip exposure opening is formed in the thermal conductive body for exposing a top surface of the chip.

9. The chip package structure as claimed in claim 1, wherein a chip accommodating cavity is formed on the bonding surface for accommodating the chip.

10. The chip package structure as claimed in claim 1, further comprising a thermal interface material (TIM) disposed between the chip and the heat sink.

11. The chip package structure as claimed in claim 1, wherein the chip is bonded to the circuit substrate by means of flip chip.

12. A heat sink for a chip package, comprising:
a thermal conductive body, having a bonding surface;
at least one passive device, embedded in the thermal conductive body; and
at least one electrical conductive terminal, connected to the passive device.

13. The heat sink for a chip package as claimed in claim 12, wherein a material of the thermal conductive body comprises ceramic material.

14. The heat sink for a chip package as claimed in claim 12, further comprising at least one bonding pad disposed on the bonding surface.

15. The heat sink for a chip package as claimed in claim 14, wherein the bonding pad is disposed in a corner of the bonding surface.

16. The heat sink for a chip package as claimed in claim 12, wherein the at least one passive device is disposed in an array in the thermal conductive body.

17. The heat sink for a chip package as claimed in claim 12, wherein the shape of the thermal conductive body is rectangular, and the at least one electrical conductive terminal is distributed along diagonal lines of the thermal conductive body.

18. The heat sink for a chip package as claimed in claim 12, wherein the at least one electrical conductive terminal is disposed in an array on the bonding surface.

19. The heat sink for a chip package as claimed in claim 12, wherein a chip exposure opening is formed in the thermal conductive body for exposing a top surface of a chip of a chip package structure.

20. The heat sink for a chip package as claimed in claim 12, wherein a chip accommodating cavity is formed on the bonding surface for accommodating a chip of a chip package structure.
